(19) United States
(12) Patent Application Publication
(10) Pub. No.: US 2006/0220144 A1
(43) Pub. Date: Oct. 5, 2006

(54) Semiconductor device and its manufacture method

(75) Inventors: Toru Anezaki, Kawasaki (JP); Jusuke Ogura, Kawasaki (JP); Taiji Ema, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/220,628

(22) Filed: Sep. 8, 2005

(30) Foreign Application Priority Data
Mar. 31, 2005 (JP) JP2005-102693

(51) Int. Cl. H01L 29/76

(52) U.S. Cl. 257/374

(57) ABSTRACT

A semiconductor device includes: a semiconductor substrate; and STIs formed in the semiconductor substrate and defining a high voltage transistor area and a low voltage transistor area, the STIs including: a first STI with a first liner including a thermal oxide film and not including a nitride film and surrounding at least a portion of the high voltage transistor area; and a second STI with a second liner of a lamination of a thermal oxide film and a nitride film and surrounding the low voltage transistor area.

### CROSS REFERENCE TO RELATED APPLICATION

This application is based on and claims priority of Japanese Patent Application No. 2005-102693 filed on Mar. 31, 2005, the entire contents of which are incorporated herein by reference.

### BACKGROUND OF THE INVENTION

A) Field of the Invention

The present invention relates to a semiconductor device and its manufacture method, and more particularly to a composite semiconductor device integrating low voltage, high speed operation micro semiconductor elements and high breakdown voltage semiconductor elements and to its manufacture method.

B) Description of the Related Art

In the broadband age, merger and adaptation to multimedia of consumer-related equipments and IT-related equipments are accelerated with the developments of digitalization. With such rapid change, it is requested to expand the functions of base systems such as servers and communication systems as well as various portable terminal apparatuses and home electronics appliances and to improve the performance several hundreds times the present performance. In order to meet these needs, designs of semiconductor devices are made at high speed and change in various ways. There are increasing requests for a semiconductor device called system on chip (SoC) implementing a plurality of functions on one chip.

There are strong demands for SoC which mounts different circuits such as low voltage operation logic circuits and high voltage operation non-volatile memories. In order to realize this, it is necessary to integrate low voltage operation logic circuits and high voltage operation non-volatile memory control circuits on the same semiconductor substrate.

Non-volatile memories include NOR type flash memories and NAND type flash memories. The former uses a voltage of about 10 V for data write through channel hot electron CHE) injection and for data read through Fowler-Nordheim (FN) tunneling. The latter uses a voltage of about 20 V for data read/write through FN tunneling. High breakdown voltage CMOS transistors are required to control such high voltages. Reliability of an insulated gate structure is an important issue of high breakdown voltage transistors.

Instead of local oxidation of silicon (LOCOS) accompanied with bird's beaks, shallow trench isolation (STI) is used for element isolation in which an isolation trench is formed and insulator or the like is buried in the trench covered with a silicon oxide film liner. A high density plasma (HDP) silicon oxide film having a good burying performance is often used as a buried insulating film. The HDP silicon oxide film has a compressive stress and degrades the transistor characteristics. To solve this, a silicon nitride liner having a tensile stress is stacked on the silicon oxide liner. After a silicon oxide film or the like to be buried in the isolation trench is deposited, an unnecessary silicon oxide film on the substrate surface is removed by chemical mechanical polishing (CMP). As a stopper for CMP, a silicon nitride film is formed on a buffer silicon oxide film on the substrate. The silicon nitride film can be used also as a hard mask for etching. After CMP, the silicon nitride film is removed with hot phosphoric acid or the like. The buffer silicon oxide film is also removed with hydrofluoric acid solution or the like. During this oxide film etching, silicon oxide of STI is also etched. If the peripheral edge of STI is etched and becomes lower than the substrate surface and if a shoulder of a nearby active region is exposed, an electric field from the gate electrode concentrates upon the shoulder so that the transistor characteristics are degraded.

US 2003-0173641 A1 (family of Japanese patent laid-open publication 2003-273206), which is incorporated herein by reference, teaches that after an STI trench is formed by etching using a hard mask made of a lamination of an oxide film and a nitride film, the oxide film is side-etched to expose a peripheral surface of an active region, and the shoulder of the active region is rounded by chemical dry etching. Electric field concentration is mitigated because of the rounded shoulder of the active region, and in addition, a damaged film formed by trench dry etching is removed so that a clean Si surface is exposed.

Rounding the shoulder and removing the damaged film (changing to an oxide film) can be realized also by thermal oxidation after etching.

In a logic circuit, a gate length of a transistor is made shorter and an operation voltage is made lower in order to meet the needs of high speed and low consumption power. For example, the specifications of a gate length of 65 nm and a power source voltage of 1.0 V are becoming the main trend. As described above, an integrated non-volatile memory requires memory control high voltage transistors and a non-volatile memory cell. Since the power source voltage for a peripheral circuit is mainly 3.3 V or 2.5 V, a middle voltage transistor is also required. A logic circuit has usually devices operating at a number of power source voltages.

A static (S) RAM is also made finer and a channel width of a MOS transistor is made as fine as about 0.12 μm. There are some restrictions of photolithography technologies in patterning an active region having a width of 0.12 μm. Photolithography using KrF excimer laser has a limit of a pattern width of about 0.14 μm, and a work for a smaller size requires photolithography using ArF excimer laser. Phenol resin is used as resist of KrF, whereas acrylic acid resin is used as resist of ArF. An etching rate ratio relative to silicon nitride is about 1 in a flat plane and about only 0.5 in a pattern corner. A bottom anti-reflection coating (BARC) film is required to reduce reflection light. Generally, an optimum thickness of the BARC film is about 80 nm. An etching rate ratio of ArF resist to the BARC film is also about 1 in a flat plane and about only 0.5 in a pattern corner. Etching resistance of ArF resist is about a half that of KrF resist.

As resist is made thick, a narrow pattern is broken down after development due to the surface tension of developing liquid. It is desired that an aspect ratio of a resist pattern is 2.5 or smaller. If a pattern width is 0.12 μm (120 nm), a resist thickness is 300 nm or thinner.

A hard mask for etching an STI trench requires a nitride film generally having a thickness of about 120 nm and an oxide film under the nitride film for protecting a silicon surface from phosphoric acid boil to be used for removing the nitride film. A BARC film having a thickness of about 80 nm is also required. ArF resist having a thickness of about 300 nm cannot endure this etching. It is desired to use a hard mask.

US 2003-0181014 A1 (family of Japanese patent laid-open publication 2003-273207), which is incorporated herein by reference, teaches a laminated hard mask of an oxide film/an amorphous silicon film/a nitride film. A silicon film has an excellent etching selectivity relative to an oxide film and a nitride film.

If a plurality type of transistors are to be integrated, the manufacture processes are influenced each other so that desired results cannot be obtained in some cases. It is desired to realize desired characteristics even if a plurality type of transistors are integrated.

### SUMMARY OF THE INVENTION

An object of the present invention is to provide a composite semiconductor device capable of integrating transistors operating at a plurality of voltages and providing a plurality type of transistors with desired characteristics.

Another object of the present invention is to provide a semiconductor device manufacture method capable of integrating transistors operating at a plurality of voltages and realizing desired characteristics of a plurality type of transistors. Another object of the present invention is to provide a semiconductor device manufacture method capable of forming high voltage transistors and low voltage transistors on the same chip and realizing desired characteristics and high reliability.

According to one aspect of the present invention, there is provided a semiconductor device comprising: a semiconductor substrate; and STIs formed in the semiconductor substrate and defining a high voltage transistor area and a low voltage transistor area, the STIs including: a first STI with a first liner including a thermal oxide film and not including a nitride film and surrounding at least a portion of the high voltage transistor area; and a second STI with a second liner of a lamination of a thermal oxide film and a nitride film and surrounding the low voltage transistor area.

Since STI surrounding the high voltage transistor area does not contain the nitride film, time-dependent change in transistor characteristics can be suppressed.

According to another aspect of the present invention, there is provided a semiconductor device manufacture method comprising the steps of: (a) etching a semiconductor substrate having a high voltage transistor area and a low voltage transistor area to form a first isolation trench surrounding the high voltage transistor area, by using a first hard mask and a resist pattern formed by first photolithography; (b) thermally oxidizing a surface of the first isolation trench; (c) etching the semiconductor substrate to form a second isolation trench surrounding the low voltage transistor area, by using a second hard mask and a resist pattern formed by second photolithography; (d) after the step (c), thermally oxidizing surfaces of the first and second isolation trenches; and (e) after the step (d), forming a nitride film liner in the first and second isolation trenches.

Thermal oxidation for STI surrounding the high voltage transistor area is performed separately from thermal oxidation for STI surrounding the low voltage transistor area. It is therefore possible to retain good high voltage transistor characteristics without adversely affecting low voltage transistors characteristics.

### BRIEF DESCRIPTION OF THE DRAWINGS

FIG. 1A to 1L are cross sectional views illustrating semiconductor device manufacture methods according to a first embodiment and its modification.

FIG. 2A to 2K are cross sectional views illustrating semiconductor device manufacture methods according to a second embodiment and its modification.

FIGS. 2LA to 2LD are plan views showing examples of a plan layout of the semiconductor device of the second embodiment and an equivalent circuit of flash memory cells.

FIGS. 2MA1 to 2TB3 are cross sectional views illustrating a semiconductor manufacture method according to the second embodiment.

FIG. 3A to 3GB3 are cross sectional views illustrating a semiconductor device manufacture method according to a third embodiment.

FIG. 4A to 4DB3 are cross sectional views illustrating a semiconductor device manufacture method according to a fourth embodiment.

### DESCRIPTION OF THE PREFERRED EMBODIMENTS

Embodiments of the present invention will be described with reference to the accompanying drawings.

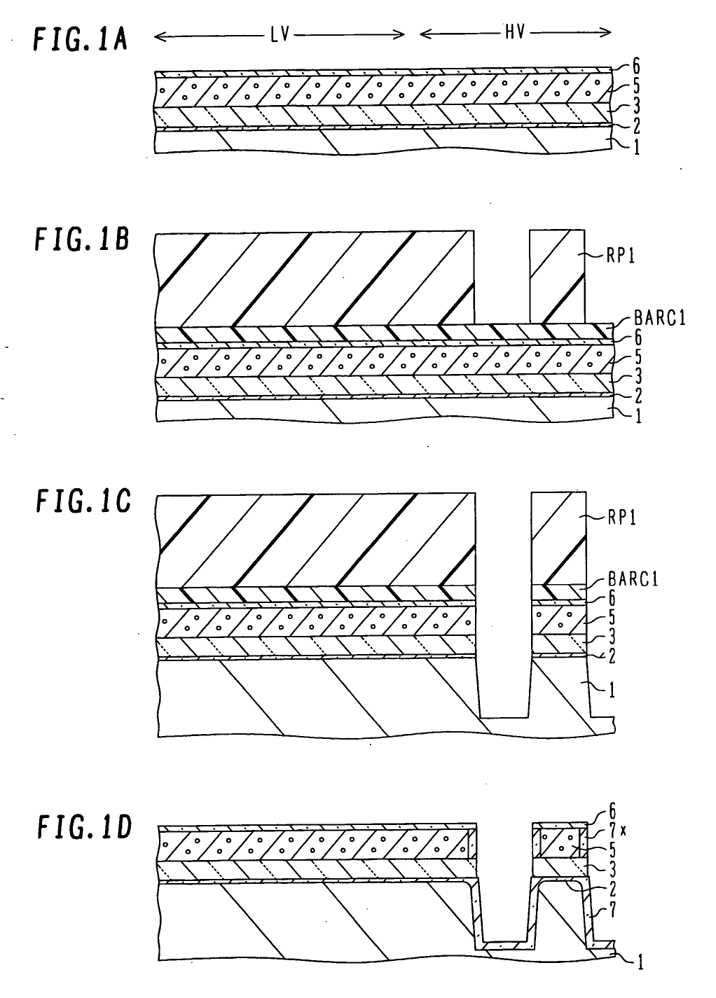

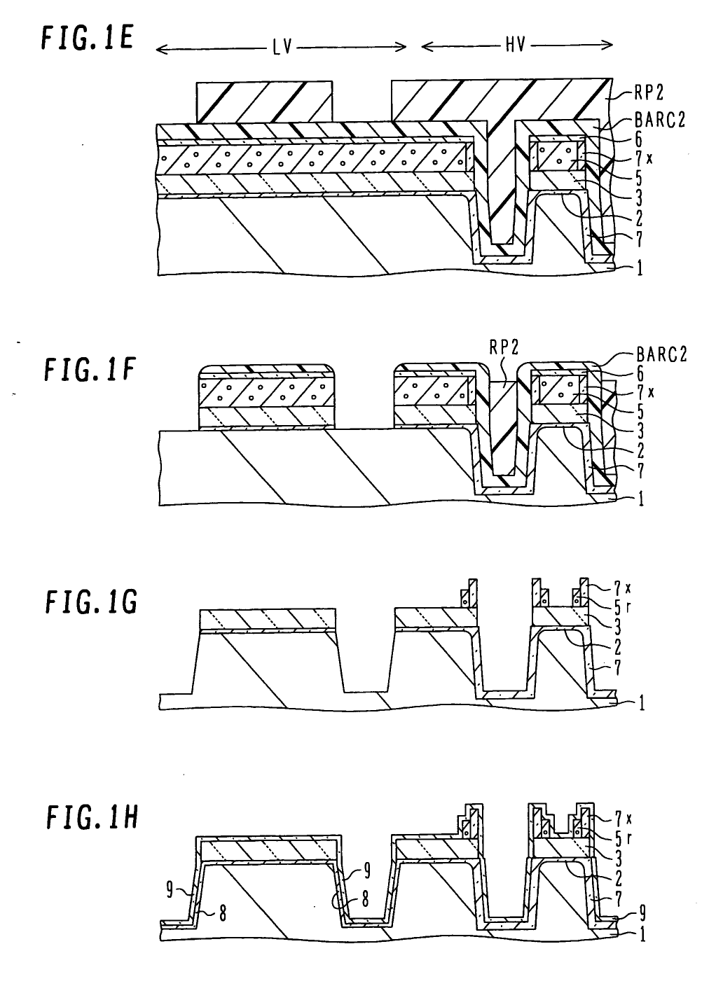

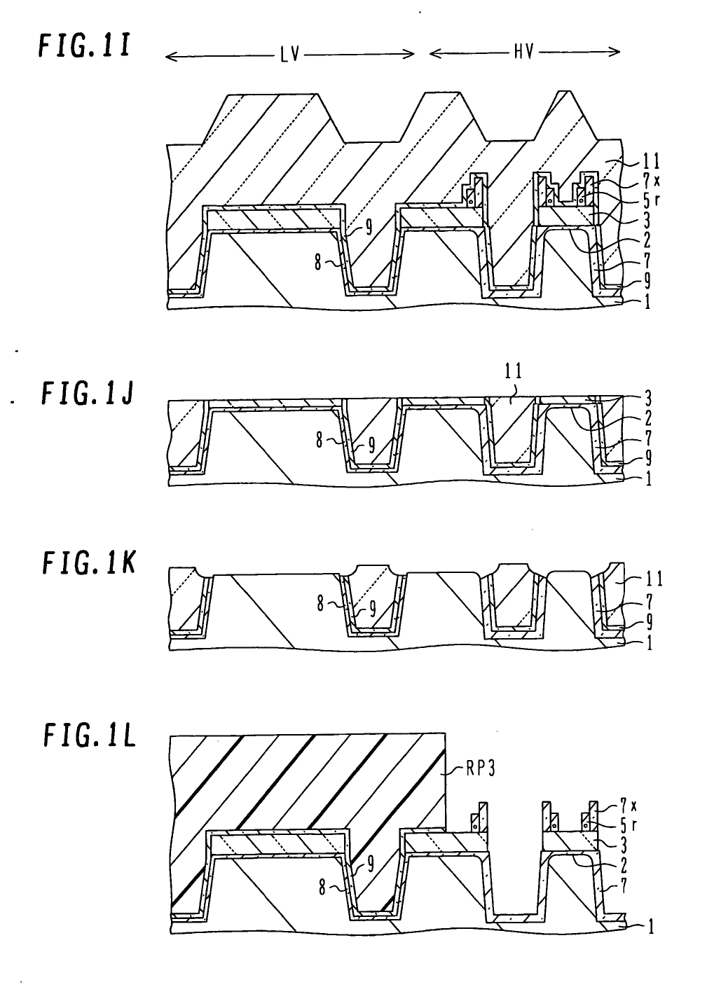

FIG. 1A to 1L are cross sectional views of a semiconductor substrate illustrating a semiconductor device manufacture method according to the first embodiment and its modification of the present invention.

As shown in FIG. 1A, a semiconductor substrate 1 made of, e.g., p-type silicon, has a low voltage area LV shown in left and a high voltage area HV shown in right. A thermal oxide film 2 having a thickness of 10 nm is grown on the surface of a semiconductor substrate, for example, by thermal oxidation, and a silicon nitride film 3 having a thickness of 120 nm is grown on the thermal oxide film by low pressure (LP) chemical vapor deposition (CVD). A polysilicon film 5 having a thickness of 150 nm is grown on the silicon nitride film 3 by CVD and a silicon nitride film 6 having a thickness of 7 nm is grown on the polysilicon film by CVD. The silicon nitride film functions as an anti-oxidation film for the polysilicon film. These films are used as a hard mask and have a stopper function for chemical mechanical polishing (CMP).

As shown in FIG. 1B, a bottom anti-reflection coating (BARC 1) film having a thickness of 80 nm and a KrF resist film having a thickness of 500 nm are coated on the silicon nitride film 6. The resist film is exposed and developed to form a resist pattern RP1 functioning as an etching mask for the high voltage area. The whole low voltage area is covered with the resist pattern RP1. Since the minimum width of an active region in the high voltage area is about 0.2 μm, KrF excimer laser can be used in the illumination system and a resist thickness may be about 0.5 μm.

As shown in FIG. 1C, the BARC 1 film, silicon nitride film 6, polysilicon film 5, silicon nitride film 3 and silicon oxide film 2 are etched to expose the silicon substrate surface, by using the resist pattern RP1 as an etching mask and mixture gas containing CF₄ such as CF₄+CHF₃+Ar as etchant gas. By changing etching gas to mixture gas containing HBr or Cl₂ such as HBr+O₂ and Cl₂+O₂, an isolation trench having a depth of about 300 nm is formed in the silicon substrate 1 by etching. Since the BARC 1 film and silicon nitride film has a selection ratio of about 2 at a flat plane and of about 1 at a corner relative to KrF resist, the lamination on the silicon substrate surface can be etched by using the resist pattern RP1 having the thickness of 500 nm. In etching the silicon substrate 1, the etched hard mask functions also as the etching mask.

As shown in FIG. 1D, after the isolation trench is formed in the high voltage area by etching, the resist pattern, if left, is removed, the BARC 1 film is removed, and the silicon oxide film 2 is side-etched by about 40 nm with hydrofluoric acid solution. Thereafter, a thermal oxide film 7 having a thickness of about 40 nm is formed on the exposed silicon surface by thermal oxidation. Since the oxidation progresses both at the upper surface and side walls because the upper surface of the peripheral area of the active region in the high voltage area is exposed by side-etching the silicon oxide film 2, the shoulder of the active region as viewed cross-sectionally is rounded. Since the radius of curvature of the shoulder cross section becomes large, electric field concentration becomes hard to occur. Although the side walls of the polysilicon film 5 are oxidized and oxide films 7x are formed, the upper surface is not oxidized because it is covered with the silicon nitride film 6.

As shown in FIG. 1E, a BARC 2 film for ArF is coated to a thickness of 80 nm and an ArF resist film is coated to a thickness of about 300 nm. The resist film is exposed with ArF excimer laser and developed to form a resist pattern RP2. Since the minimum width of an active region in the low voltage area is about 120 nm, ArF photolithography is preferable, and a height of the resist mask RP2 is preferably limited to about 300 nm.

As shown in FIG. 1F, the BARC 2 film, silicon nitride film 6, polysilicon film 5, silicon nitride film 3 and silicon oxide film 2 are etched by using the resist pattern RP2 as an etching mask and, for example, mixture gas containing CF₄ as etchant gas.

Since the films to be etched have a selection ratio of about 1, the etching progresses on a flat plane to the degree that the BARC 2 film is slightly left. At the pattern corner, since plasma is concentrated by the electric concentration, the selection ratio lowers to about 0.7, the peripheral area of the polysilicon film 5 is etched.

As shown in FIG. 1G, the left BARC 2 film (and resist pattern if left) are removed. By using the hard mask as an etching mask, the silicon substrate 1 is etched to a depth of about 300 nm by using, for example, the mixture gas containing HBr or Cl₂. Since silicon and oxide film have a selection ratio of about 20, the silicon substrate 1 covered with the oxide film 7 in the high voltage area is hardly damaged by etching. The thin nitride film 6 is etched, and the polysilicon film 5 is also etched during etching silicon. While the polysilicon film 5 is etched as a dummy, the underlying silicon nitride film 3 will not be etched. The nitride film 3 functions as an etch stopper. The oxide films 7x formed in the process shown in FIG. 1D are not completely etched and it is considered that residues 7r and silicon residues 5r on the side walls of the residues 7r are left.

As shown in FIG. 1H, after the isolation trench is formed in the low voltage area by etching, the silicon surface exposed on the trench surface is thermally oxidized to form a buffer thermal oxide film 8 having a thickness of about 5 nm. Although the high voltage area is also exposed in an oxidizing atmosphere, since the silicon oxide film 7 having the thickness of about 40 nm is already formed, an increase of a thickness of the oxide film is small. Only the thermal oxide film having the thickness of about 5 nm is formed on the side wall of the active region in the low voltage area. Therefore, the radius of curvature of the shoulder in the active region cross section is smaller than that of the shoulder in the active region cross section in the high voltage area. Next, a silicon nitride film 9 is deposited on the whole substrate surface to a thickness of about 5 nm by LPCVD. This silicon nitride film 9 has a tensile stress and is cancelled out by a compressive stress of the silicon oxide to be later buried in the isolation trench to thereby retain transistor ability.

As shown in FIG. 11, a silicon oxide film 11 is deposited to a thickness of about 500 nm by high density plasma (HDP) to bury the isolation trench. STI is therefore formed having an ONO structure of an oxide film (O)/a nitride film (N)/an oxide film (O). Another film forming method may be used if the isolation trench can be buried and a good insulating film can be formed.

As shown in FIG. 1J, the HDP silicon oxide film is polished by chemical mechanical polishing (CMP) to remove the HDP oxide film 11 on the flat surface and leave the silicon oxide film 11 only in the isolation trench. The silicon nitride film 3 functions as a stopper for CMP. After STI is completed, it is necessary to remove the silicon nitride film 3 and buffer silicon oxide film 2 before a gate insulating film is formed.

As shown in FIG. 1K, the silicon nitride film 3 is removed with phosphoric acid boil and the silicon oxide film 2 is removed with hydrofluoric acid solution. The liner 7 and buried film 11 of silicon oxide in the isolation trench is also subjected to etching with the hydrofluoric acid solution. In the high voltage area, since the radius of curvature of the shoulder in the active region cross section is made large by the thermal oxidation shown in FIG. 1D, a threshold value change can be reduced at opposite ends of the channel region when a MOS transistor is formed.

In the process shown in FIG. 1H, both in the low and high voltage areas, the nitride film liner 9 is formed in common on the oxide film liners 8 and 7 in the isolation trenches and the buried oxide film 11 is deposited on the nitride film liner 9. The nitride film in the high voltage area is preferably removed if there is a possibility that the nitride film of the ONO structure in the high voltage area operates as a trap of charge carriers.

As shown in FIG. 1L, after the silicon nitride film 9 is deposited in the process of FIG. 1H, an i-line resist pattern RP3 is formed to expose a desired high voltage area, and the silicon nitride film 9 is etched and removed with etchant gas containing C₄F₈. For example, if a high voltage of about 20 V is used as in a NAND type flash memory cell, there is a possibility that the ONO structure traps charges and a threshold value is shifted. In such a case, it is preferable to remove the silicon nitride film.

In the first embodiment, although the hard mask including the polysilicon film is used, the hard mask of the polysilicon is not necessarily required in KrF lithography because the resist film can be made thick.

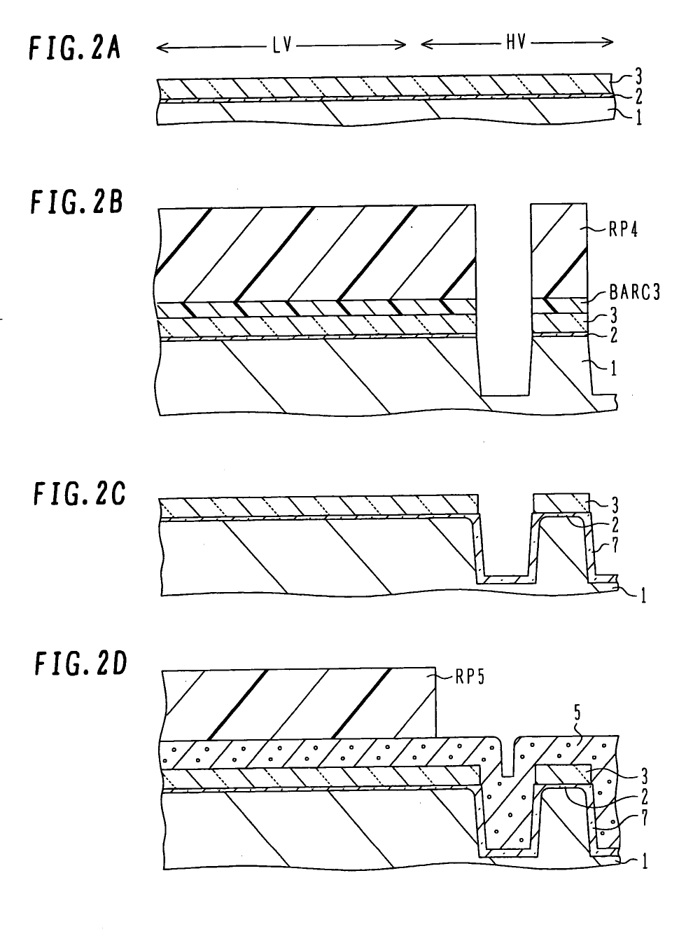

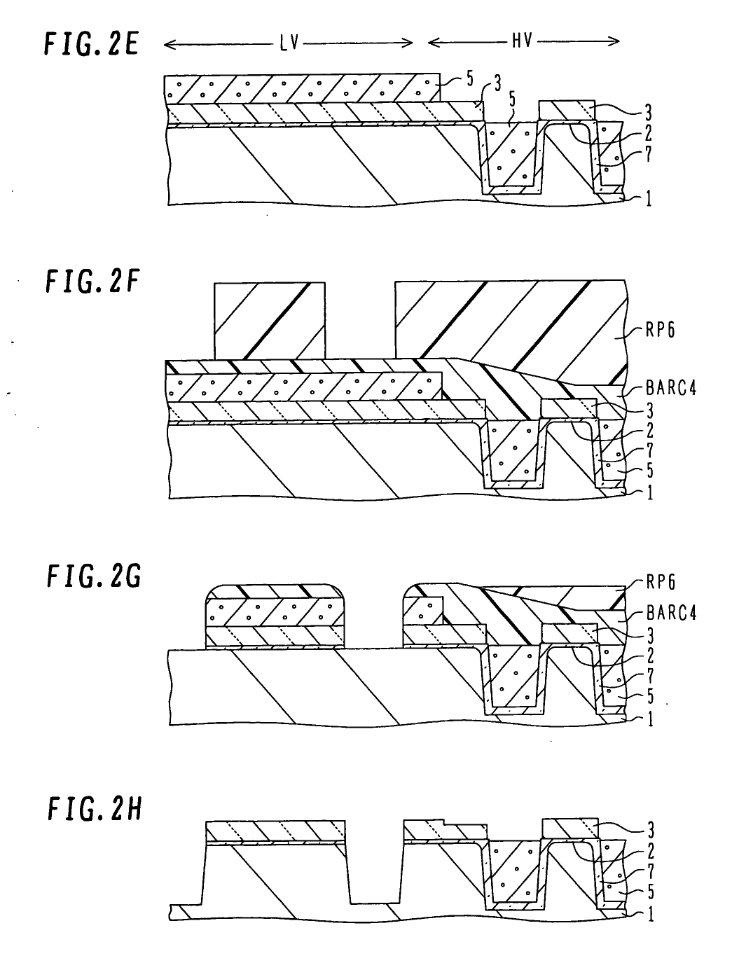

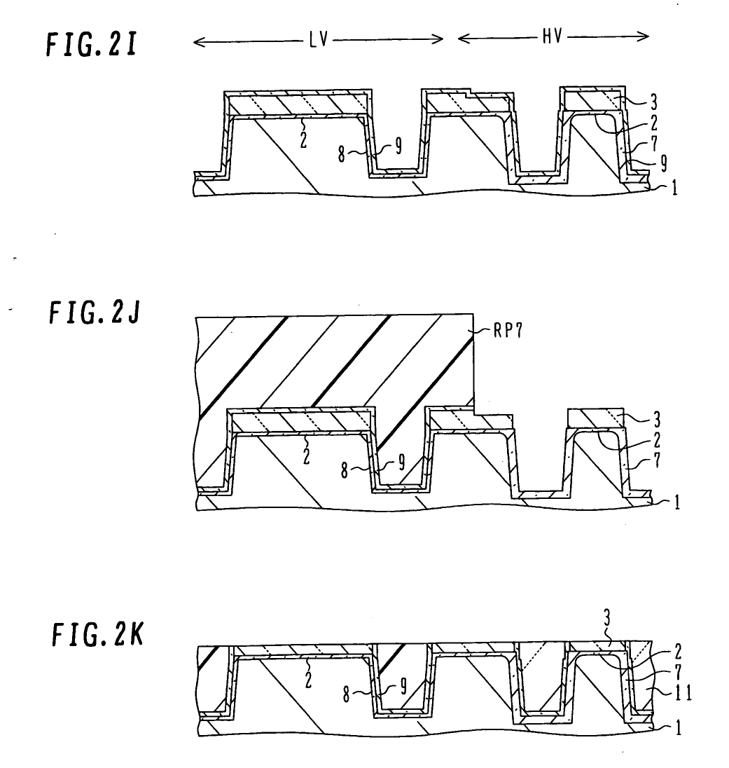

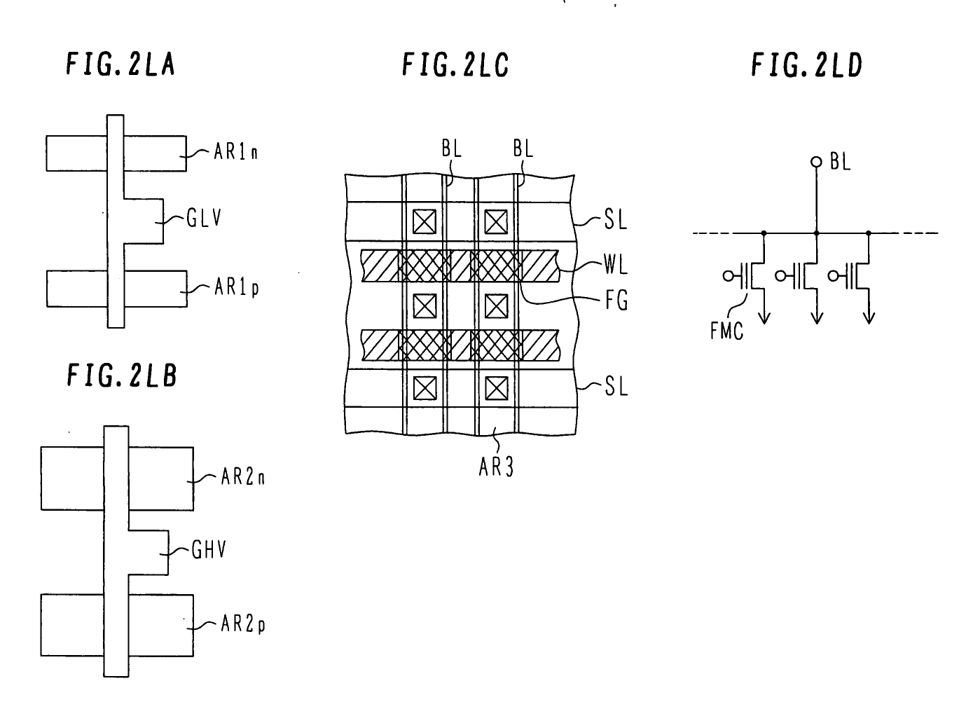

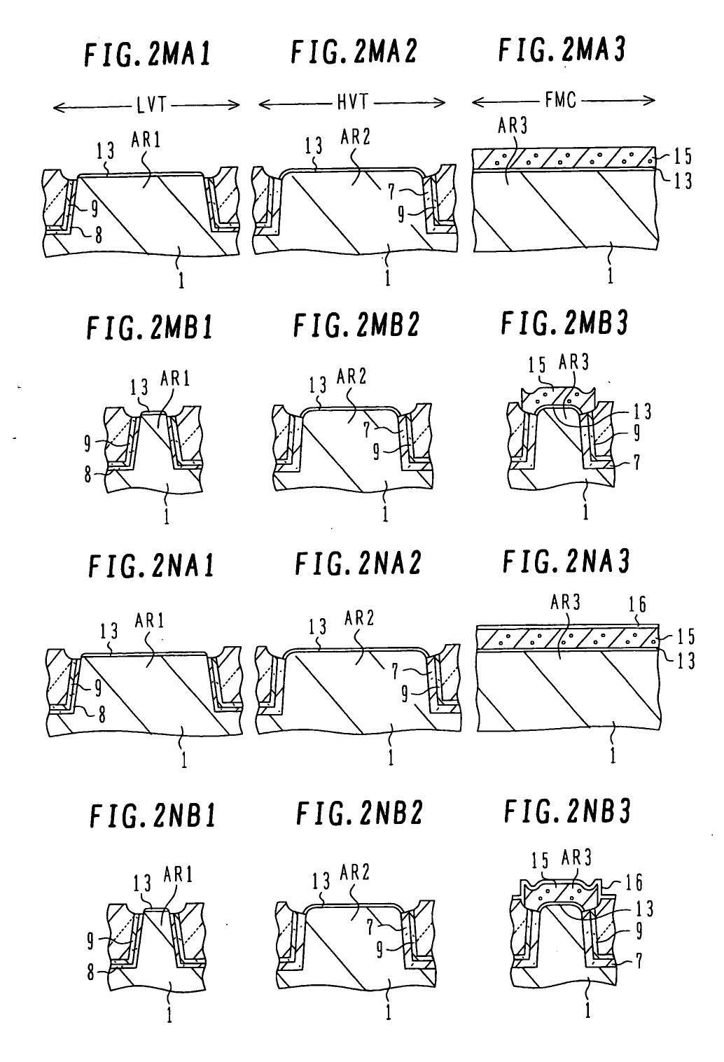

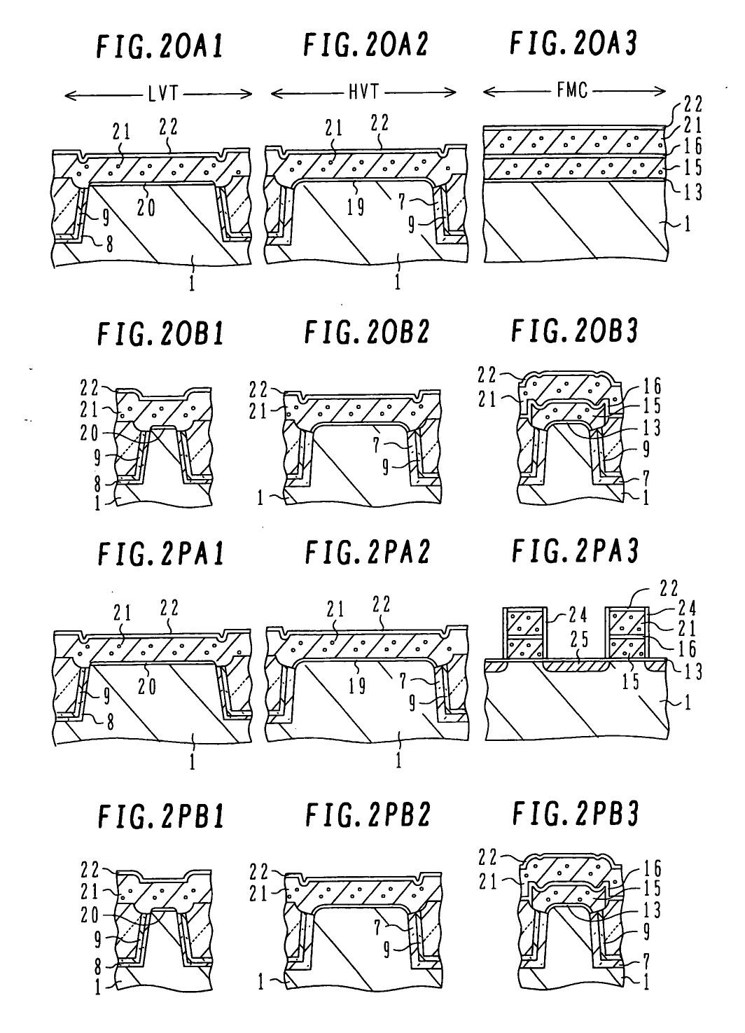

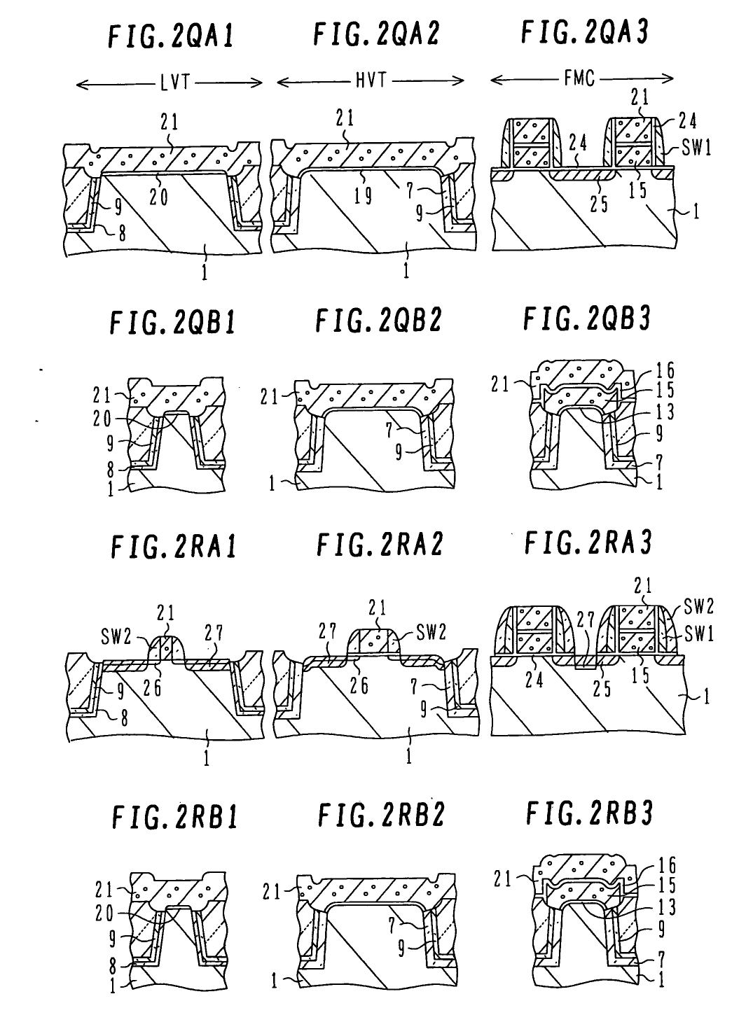

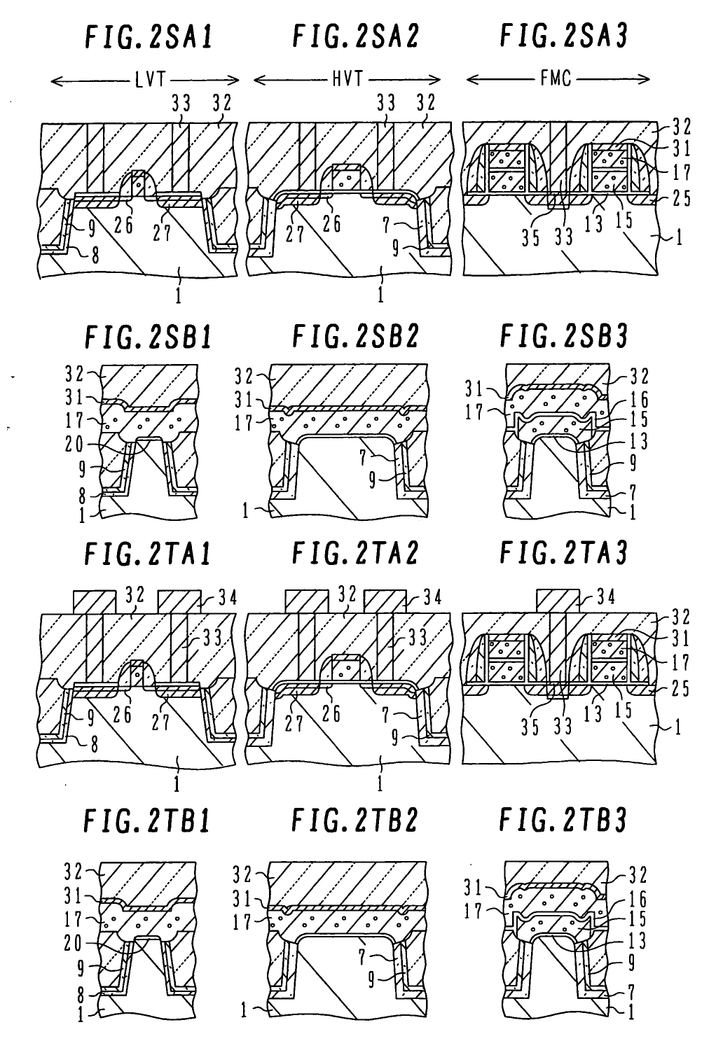

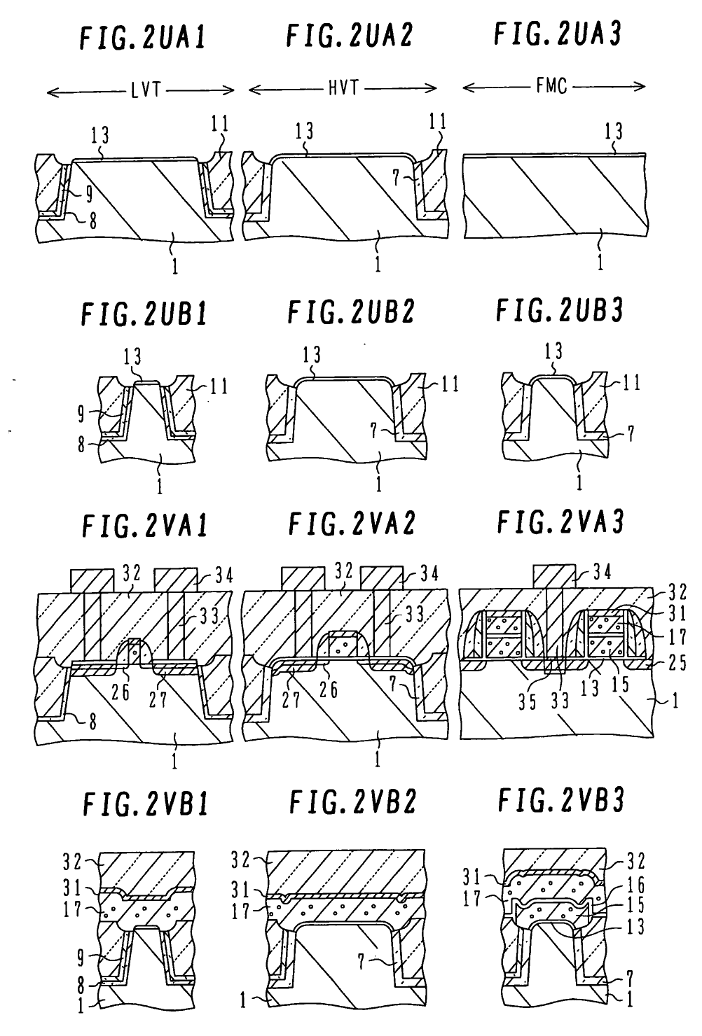

FIGS. 2A to 2K are cross sectional views of a semiconductor substrate illustrating the second embodiment and its modification.

As shown in FIG. 2A, the surface of a silicon substrate 1 is thermally oxidized to form a thermal oxide film 2 having a thickness of about 10 nm, and a silicon nitride film 3 having a thickness of about 120 nm is deposited on the thermal oxide film by LPCVD.

As shown in FIG. 2B, a BARC 3 film having a thickness of about 80 nm and a KrF resist film having a thickness of about 500 nm are coated on the silicon nitride film 3, and the resist film is exposed with KrF excimer laser and developed to form a resist pattern RP4. By using the resist pattern RP4 as an etching mask, similar to the first embodiment, the BARC 3 film, silicon nitride film 3 and silicon oxide film 2 are etched and the silicon substrate 1 is etched by a depth of about 300 nm. The resist pattern RP4 is thereafter removed.

As shown in FIG. 2C, the silicon oxide film 2 is side-etched by wet etching using hydrofluoric acid solution to retract the side walls of the silicon oxide film 2 by about 40 nm, and a thermal oxide film 7 having a thickness of about 40 nm is formed by thermal oxidation. As described with reference to FIG. 1D, the side walls of the isolation trench surrounding the active region in the high voltage area and the upper surface of the peripheral area of the active region are oxidized so that the radius of curvature of the shoulder in the active region cross section becomes large. Since the polysilicon film is not formed on the silicon nitride film 3, the side wall oxide films 7x shown in FIG. 1F, i.e., the silicon oxide residues 7r shown in FIG. 1G are not formed.

As shown in FIG. 2D, a polysilicon film 5 is deposited to a thickness of about 150 nm. If necessary, an i-line resist film is coated, exposed and developed to form a resist pattern RP5 having an opening exposing the high voltage area. Since the polysilicon film 5 is not necessary to be protected from oxidation, the silicon nitride film 6 shown in FIG. 1A is not formed.

As shown in FIG. 2E, the polysilicon film 5 is etched by about 300 nm by using mixture gas containing HBr or Cl₂ as etchant gas. Thereafter, the resist pattern RP5 is removed. This etching reduces the degree of surface irregularity of the polysilicon film 5 above the isolation trench. If surface flatness is not required severely, e.g., if the isolation trench is buried with the polysilicon film or the like, the processes of forming the resist pattern RP5 and etching back the polysilicon film may be omitted.

As shown in FIG. 2F, a BARC 4 film for ArF having a thickness of about 80 nm and a resist film for ArF having a thickness of about 300 nm are coated, and the resist film is exposed with ArF excimer laser to form a resist pattern RP6 for the low voltage area.

As shown in FIG. 2G, the polysilicon film 5, silicon nitride film 3 and silicon oxide film 2 are etched by using the ArF resist pattern RP6 as an etching mask. The resist pattern RP6 and BARC 4 film are thereafter removed.

As shown in FIG. 2H, the silicon substrate 1 is etched by a process similar to that of the first embodiment, by using the patterned silicon nitride film 3 as a substantial hard mask. During this silicon etching, the polysilicon film 5 is removed. The polysilicon film 5 deposited in the isolation trench in the high voltage area is also removed.

As shown in FIG. 21, an oxide film 8 having a thickness of about 5 nm is formed by thermal oxidation to protect the surface of the isolation trenches. Since the silicon surface covered with the oxide film 7 having a thickness of about 40 nm is less oxidized, an increase of the thickness of the oxide film 7 is small. Similar to the first embodiment, the shoulder in the active region cross section in the high voltage area has a radius of curvature larger than that of the shoulder in the low voltage area. Thereafter, a silicon nitride film 9 having a tensile stress is deposited to a thickness of about 5 nm by LPCVD. As described earlier, the silicon nitride film having a tensile stress has a function of cancelling out a compressive stress of silicon oxide buried in the isolation trench.

As shown in FIG. 2J, if necessary, a resist pattern RP7 is formed having an opening exposing the high voltage area and the silicon nitride film 9 in the high voltage area may be removed. If there is a possibility that the silicon nitride film traps charges, the silicon nitride film is removed to reduce a subsequent change in the threshold value. The process shown in FIG. 2J is executed if necessary, and is not an essential process. In the following description, it is assumed that the silicon nitride film is not removed.

As shown in FIG. 2K, similar to the first embodiment, an HDP silicon oxide film 11 is deposited to a thickness of about 500 nm to bury the isolation trenches, and thereafter an unnecessary HDP oxide film on the substrate surface is removed by CMP. The structure shown in FIG. 1J of the first embodiment is almost the same as that shown in FIG. 2K of the second embodiment. Similar to the process shown in FIG. 1K of the first embodiment, the silicon nitride film 3 and silicon oxide film 2 are removed.

In the following, description will be made on a semiconductor device having low voltage transistors in a low voltage area and high voltage transistors and flash memories in a high voltage area.

FIG. 2LA shows an example of a plan layout of the low voltage transistor area. An n-type active region AR1n and a p-type active region AR1p define one CMOS area. An insulated gate structure GLV having a gate length of about 65 nm is formed crossing a middle area of each of the active regions AR1n and AR1p. A channel width of each of the active regions AR1n and AR1p is about 0.12 μm at a minimum.

FIG. 2LB shows an example of a plan layout of the high voltage transistor area. An n-type active region AR2n and a p-type active region AR2p define one CMOS area. An insulated gate structure GHV having a gate length of about 65 nm is formed crossing a middle area of each of the active regions AR2n and AR2p. In the following description, n-channel transistors are used by way of example.

FIG. 2LC is a plan view briefly showing the structure of a flash memory circuit. A plurality of active regions AR3 extending in a vertical direction in FIG. 2LC are disposed in parallel, and a plurality of word lines WL are formed in parallel in a horizontal direction in FIG. 2LC, crossing the active regions AR3. The word line WL has a structure that a laterally continuous control gate is stacked above floating gates FG formed separately for respective memory cells. A region sandwiched between two word lines WL is a drain region common to two memory cells and is connected to a bit line BL extending in the vertical direction. Source regions are formed in the region opposite to the drain region relative to the word line WL and connected to source lines SL.

FIG. 2LD is an equivalent circuit diagram of the flash memory circuit. A plurality of flash memory cells FMC are disposed in parallel and connected to the bit line BL. Information written in the floating gates can be read selectively by controlling each flash memory cell and reading written information.

FIGS. 2MA1, 2MA2 and 2MA3 are cross sectional views of active regions along a channel direction (perpendicular to a gate extending direction), respectively of a low voltage transistor LVT, a high voltage transistor HVT and a flash memory cell FMC. FIGS. 2MB1, 2MB2 and 2MB3 are cross sectional views of active regions along the gate extending direction perpendicular to FIGS. 2MA1, 2MA2 and 2MA3. In the following, characters following A and B of drawing symbols indicate similar meanings. If characters following A and B are omitted, such as FIG. 2M, these characters represent all six drawings.

As shown in FIG. 2M, a tunnel oxide film (as composition, a silicon oxynitride film) 13 having a thickness of about 10 to 15 nm is formed on the surface of the flash memory active region AR3. Also in other active regions, the oxide film 13 is formed tentatively.

As shown in FIG. 2M, a doped amorphous silicon film 15 is deposited to a thickness of about 90 nm by LPCVD and patterned in a stripe shape along each active region in order to form floating gates. At the same time, the amorphous silicon film 15 in an area other than the flash memory area are removed.

As shown in FIG. 2N, a silicon oxide film having a thickness of about 6 nm is deposited by LPCVD on the upper surface of the substrate, covering the silicon film 15. A silicon nitride film is formed on the silicon oxide film to a thickness of about 5 nm by LPCVD. Wet oxidation is performed at 800° C. for about 20 minutes to form an ONO insulating film 16. The ONO insulating film 16 and tunnel oxide film 13 in the low voltage transistor area LVT and high voltage transistor area HVT are selectively removed to expose silicon surface in these areas.

As shown in FIG. 20, a silicon oxide film 19 having a thickness of about 15 nm suitable for a high voltage transistor is grown by thermally oxidizing the exposed silicon surface. The silicon oxide film 19 in the low voltage transistor area is removed and a new silicon oxynitride film 20 is formed having a thickness of about 2 nm or thinner. In the flash memory cell area, since the surface is covered with the ONO insulating film 16, thermal oxidation hardly occurs. Thereafter, a polysilicon film 21 is deposited to a thickness of about 100 nm by LPCVD, and an anti-reflection film 22 of silicon nitride is deposited on the polysilicon film to a thickness of about 29 nm by plasma CVD.

As shown in FIG. 2P, in the flash memory cell area, the laminated gate electrodes are patterned. In this case, the low voltage transistor area and high voltage transistor area are covered with a resist mask to leave the whole polysilicon film 20. Thereafter, As⁺ ions are implanted into the flash memory area at an acceleration energy of 30 keV and a dose of about 5×10¹⁴ cm⁻² (denoted as 5E14 or the like) to form source/drain regions 25 of the flash memory cell. The resist mask is removed after pattering the laminated gate electrodes or after ion implantation. Oxide films 24 are formed by thermally oxidizing the side walls of the laminated gate electrodes. A silicon oxide film is also formed on the silicon surface.

As shown in FIG. 2Q, a silicon nitride film is deposited on the whole substrate surface to a thickness of about 100 nm by LPCVD and anisotropically etched to form side wall spacers SW1 on the side walls of the laminated gate electrodes. Anisotropic etching of the silicon nitride film removes the silicon nitride film 22 on the polysilicon film 21.

As shown in FIG. 2R, a resist mask is formed on the polysilicon film 21 in the low voltage transistor area and high voltage transistor area, and the polysilicon film is patterned to form gate electrodes. By using the gate electrodes as a mask, n-type impurity ions are implanted to form desired extensions 26. A TEOS oxide film is deposited to a thickness of about 100 nm and anisotropically etched to form side wall spacers SW2 of silicon oxide on the side walls of each gate and on the side walls of the side wall spacers SW1 of the laminated gate electrodes.

After the side wall spacers SW2 are formed, impurity ions are implanted at a high concentration into the source/drain regions to form high impurity concentration source/drain regions 27.

As shown in FIG. 2S, a Co film is formed on the substrate surface by sputtering, and annealing is performed at about 600° C. to selectively form CoSi only on the silicon surface. An unreacted Co film is removed with SCl washing liquid. If necessary, annealing is further performed to form low resistance silicide layers 31. Thereafter, an interlayer insulating film 32 of silicon oxide or the like is formed, contact holes are formed through the interlayer insulating film, and conductive plugs 33 of tungsten or the like are buried in the contact holes.

As shown in FIG. 2T, a wiring layer is formed on the interlayer insulating film 32, patterned to form wirings 34. Thereafter, if necessary, the process of forming an interlayer insulating film and wirings is repeated to form a multi-layer wiring structure.

In the above description, the silicon nitride film is formed also in the high voltage transistor area. With reference to FIGS. 2U and 2V, description will be made on a semiconductor device with the silicon nitride film being removed in the high voltage transistor area as shown in FIGS. 1L and 2G.

FIG. 2U shows a tunnel oxide film 13 to be used in the flash memory cell area. In the high voltage transistor area and flash memory cell area, the STI liner is made of only a thick oxide film 7 and a silicon nitride film is not used.

FIG. 2V shows a low voltage transistor, a high voltage transistor and a flash memory cell covered with an interlayer insulating film 32, with conductive plugs 33 being buried and wirings 34 being formed.

In the embodiments described above, a photolithography process is performed twice independently for the high voltage transistor area and low voltage transistor area. Since the surface of the isolation trench in the high voltage transistor area is oxidized before the STI trench is formed in the low voltage transistor area, an oxidation degree can be controlled independently for the low voltage transistor area and high voltage transistor area. There is therefore a degree of freedom in selecting the radius of curvature of a shoulder in the active region cross section in the high voltage transistor area.

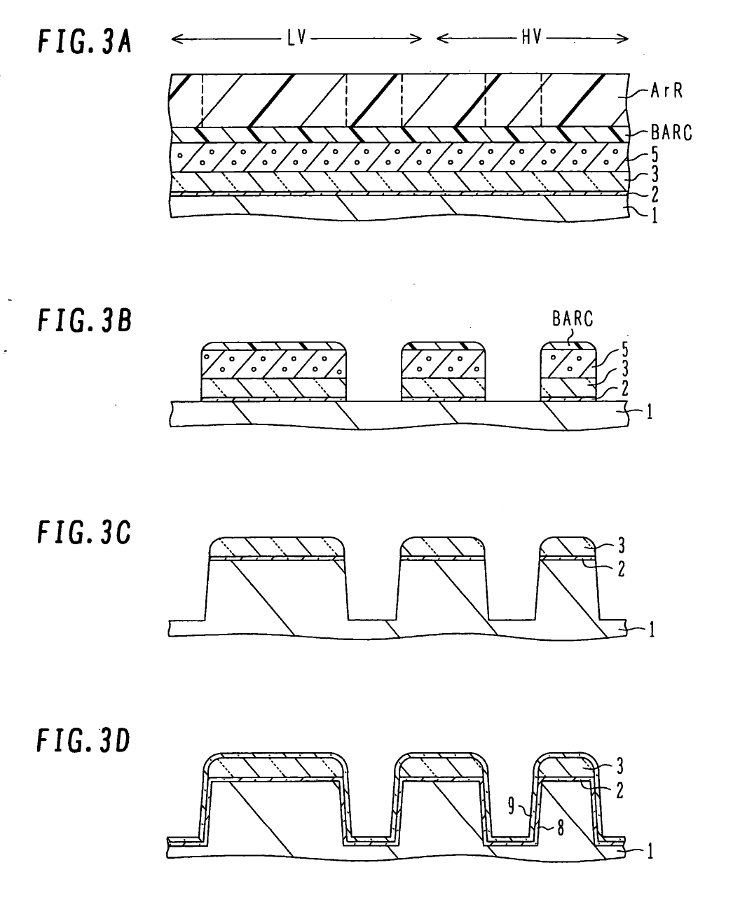

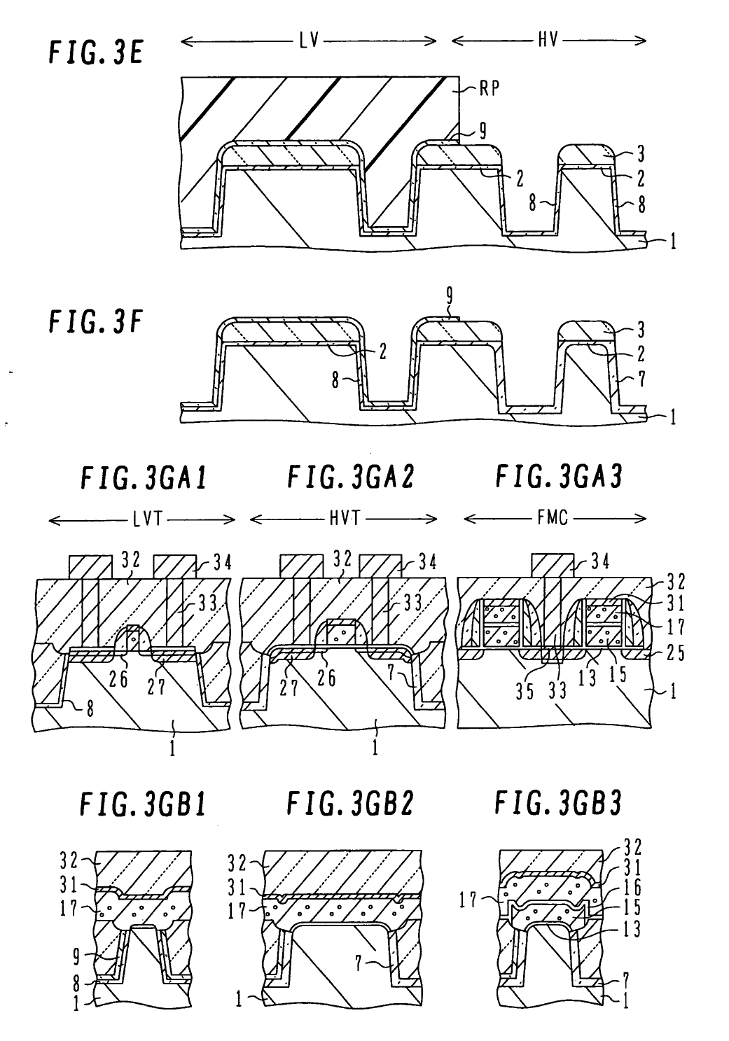

Two photolithography processes complicate the manufacture processes. It is possible to form an isolation trench both in the low voltage transistor area and high voltage transistor area at the same time. FIGS. 3A to 3G are cross sectional views illustrating a semiconductor device manufacture method according to the third embodiment.

As shown in FIG. 3A, the surface of a silicon substrate 1 is thermally oxidized to form a thermal oxide film 2 having a thickness of 10 nm. A silicon nitride film 3 is grown on the thermal oxide film to a thickness of 120 nm by LPCVD. A polysilicon layer 5 is grown on the silicon nitride film to a thickness of 150 nm. A BARC film is coated on the polysilicon layer 5 to a thickness of about 80 nm, and an ArF resist film ArR is coated on the BARC film. Since the minimum pattern width in the low voltage transistor area is about 120 nm, a thickness of the resist film ArR is set to about 300 nm. The resist film ArR is exposed with ArF excimer laser and developed to form a resist pattern having a shape corresponding to respective active regions.

As shown in FIG. 3B, by using the resist pattern as an etching mask, the BARC film, polysilicon film 5, silicon nitride film 3 and oxide film 1 are etched. A selection ratio of these films relative to the resist film is about 1. Therefore, etching progresses to the degree that the BARC film is left slightly on the flat plane. At the pattern corner, since plasma is concentrated by the electric concentration, the selection ratio lowers to about 0.7 so that etching progresses to an intermediate depth of the polysilicon film 5.

As shown in FIG. 3C, by using the polysilicon film 5 and silicon nitride film 3 as an etching mask, the silicon substrate 1 is etched to a depth of about 300 nm. The polysilicon layer 5 is removed during silicon etching and the silicon nitride film 3 functions as a hard mask.

As shown in FIG. 3D, the exposed silicon surface is thermally oxidized to grow an oxide film 8 having a thickness of about 5 nm. Thereafter, a silicon nitride film 9 is grown on the whole substrate surface to a thickness of about 5 nm by LPCVD. Similar to the embodiments described above, the silicon nitride film 9 having a tensile stress cancels out a compressive stress of a buried oxide film to be formed later.

As shown in FIG. 3E, the low voltage transistor area is covered with an i-line resist pattern RP, and the silicon nitride film 9 in the isolation trench in the high voltage transistor area HV is removed.

As shown in FIG. 3F, the silicon oxide film 2 is side-etched by about 40 nm by wet etching using hydrofluoric acid solution. The silicon oxide film 8 exposed in the isolation trench in the high voltage transistor area HV is etched and removed. The resist pattern RP is thereafter removed, and thermal oxidation is performed to grow a silicon oxide film 7 having a thickness of about 40 nm. In the low voltage transistor area LV, since the substrate surface is covered with the silicon nitride film 9, oxidation can be avoided.

Thereafter, similar to the embodiment described above, an HDP silicon oxide film is deposited to a thickness of about 500 nm to bury the isolation trench. An unnecessary HDP silicon oxide film on the substrate surface is removed by CMP, the silicon nitride film is removed with phosphoric acid boil, and the silicon oxide film 2 on the active region surface is removed with hydrofluoric acid solution. A low voltage transistor, a high voltage transistor and a flash memory cell are formed being covered with an interlayer insulating film, with conductive plugs being buried and wirings being formed.

FIGS. 3GA1, 3GA2, 3GA3, 3GB1, 3GB2 and 3GB3 are cross sectional views of active regions along a channel direction and along a word line direction, respectively of the low voltage transistor, high voltage transistor and flash memory cell of the semiconductor device manufactured by the processes described above. The structure is similar to that shown in FIG. 2V.

In this embodiment, the radius of curvature of the shoulder in the active region cross section in the high voltage transistor area is set larger than that of the shoulder in the active region cross section in the low voltage transistor area. Although it is necessary to suppress a threshold value change by the silicon nitride film in the high voltage transistor area, there is a case wherein the deterioration of the characteristics of low voltage transistors is permitted to some extent. An embodiment for this case will be described below.

First, the processes shown in FIGS. 3A to 3C are executed to form the isolation trenches.

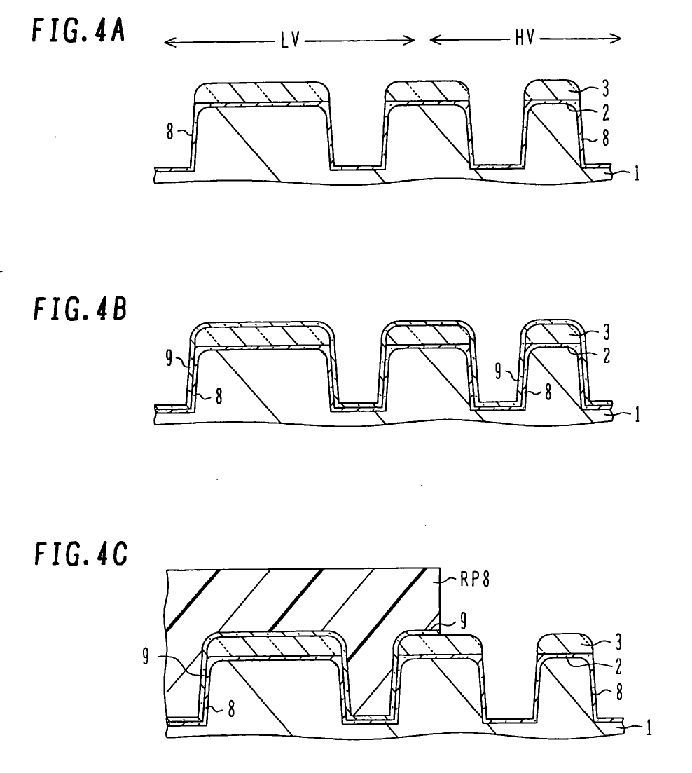

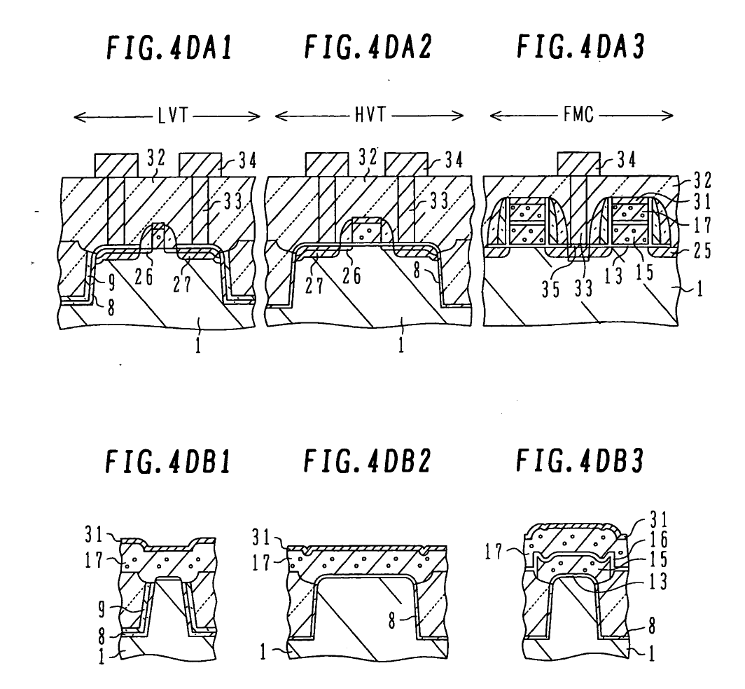

As shown in FIG. 4A, the silicon oxide film 2 on the active region surface is side-etched with hydrofluoric acid solution to retract it by a width of about 20 nm. Thereafter, a silicon oxide film 8 is grown to a thickness of about 20 nm by thermal oxidation to cover the surfaces of the isolation trenches with the silicon oxide film 8. Since the silicon oxide film 2 in the peripheral surface area of the active region is removed, oxidation progresses also from the surface of the active region so that the shoulder in the active region cross section is rounded. In order to suppress the deterioration of the characteristics of low voltage transistors, a thickness of the oxide film 8 is limited and rounding the shoulder of the active region is suppressed less than some degree.

As shown in FIG. 4B, a silicon nitride film 9 is deposited to a thickness of about 5 nm by LPCVD. As described earlier, a tensile stress of the silicon nitride film 9 is cancelled out by a compressive stress of the buried oxide film to retain the transistor performance.

As shown in FIG. 4C, the low voltage transistor area LV is covered with an i-line resist pattern RP8 and the silicon nitride film 9 in the high voltage transistor area is removed. The resist pattern RP8 is thereafter removed. An HDP silicon oxide film is deposited to bury the isolation trenches, an unnecessary HDP silicon oxide film on the substrate surface is removed by CMP, and the silicon nitride film 3 and silicon oxide film 2 are removed. A gate electrode structure, source/drain regions, silicide layers are formed in each active region, an interlayer insulating film is deposited, conductive plugs are buried in contact holes, and wirings are formed.

FIGS. 4DA1, 4DA2, 4DA3, 4DB1, 4DB2 and 4DB3 show the structures of a low voltage transistor LVT, a high voltage transistor HVT and a flash memory cell FMC. STI surrounding the low voltage transistor has a laminated liner of the silicon oxide film/the silicon nitride film which liner cancels out a compressive stress of the buried silicon oxide to retain a high transistor performance. STI in the high voltage transistor area does not have a silicon nitride liner so that it is possible to prevent the phenomenon of trapping charges and changing the threshold value. Each active region cross section is rounded to some extent so that an electric field concentration under the gate electrode can be mitigated to some extent.

According to the embodiment shown in FIGS. 3A to 3G and the embodiment shown in FIGS. 4A to 4D, side-etching the silicon oxide film and thermally oxidizing the silicon surface are performed by the same processes for both the high voltage transistor area and low voltage transistor area so that the same radius of curvature of each shoulder in the active region cross section is obtained, which requires some compromise between different requirements. However, the number of processes is small and the manufacture processes are not complicated.

The present invention has been described in connection with the preferred embodiments. The invention is not limited only to the above embodiments. It will be apparent to those skilled in the art that other various modifications, improvements, combinations, and the like can be made.

What we claim are:

1. A semiconductor device comprising:
a semiconductor substrate; and
STIs formed in said semiconductor substrate and defining a high voltage transistor area and a low voltage transistor area, said STIs including: a first STI with a first liner including a thermal oxide film and not including a nitride film and surrounding at least a portion of said high voltage transistor area; and a second STI with a second liner of a lamination of a thermal oxide film and a nitride film and surrounding said low voltage transistor area.

2. The semiconductor device according to claim 1, wherein the thermal oxide film of said first liner is thicker than the thermal oxide film of said second liner, and a radius of curvature in a vertical cross section in at least part of said high voltage transistor area is larger than a radius of curvature in a vertical cross section in said low voltage transistor area.

3. The semiconductor device according to claim 1, wherein a high voltage transistor in said high voltage transistor area has an operation voltage of 5 V or higher, and a low voltage transistor in said low voltage transistor area has an operation voltage of 1.2 V or lower.

4. A semiconductor device comprising:
a semiconductor substrate; and
STIs formed in said semiconductor substrate and defining a high voltage transistor area and a low voltage transistor area, said STIs including: a first STI with a first liner including a lamination of a thermal oxide film and a nitride film and surrounding at least a portion of said high voltage transistor area; and a second STI with a second liner of a lamination of a thermal oxide film and a nitride film and surrounding said low voltage transistor area,
wherein the thermal oxide film of said first liner is thicker than the thermal oxide film of said second liner, and a radius of curvature in a vertical cross section in at least part of said high voltage transistor area is larger than a radius of curvature in a vertical cross section in said low voltage transistor area.

5. A semiconductor device manufacture method comprising the steps of:
(a) etching a semiconductor substrate having a high voltage transistor area and a low voltage transistor area to form a first isolation trench surrounding said high voltage transistor area, by using a first hard mask and a resist pattern formed by first photolithography;
(b) thermally oxidizing a surface of said first isolation trench;
(c) etching said semiconductor substrate to form a second isolation trench surrounding said low voltage transistor area, by using a second hard mask and a resist pattern formed by second photolithography;
(d) after said step (c), thermally oxidizing surfaces of said first and second isolation trenches; and
(e) after said step (d), forming a nitride film liner in said first and second isolation trenches.

6. The semiconductor device manufacture method according to claim 5, wherein said first photolithography is photolithography using KrF excimer laser and said second photolithography is photolithography using ArF excimer laser.

7. The semiconductor device manufacture method according to claim 5, further comprising the step of:
(f) after said step (e), burying said first and second isolation trenches with insulator.

8. The semiconductor device manufacture method according to claim 7, further comprising the step of:
(g) between said steps (e) and (f), removing the nitride film liner in said second isolation trench.

9. The semiconductor device manufacture method according to claim 5, wherein:
said first hard mask includes a lamination of an oxide film and a nitride film; and
the method further comprises the step of:
(bx) before said step (b), side-etching the oxide film of said first hard mask.

10. The semiconductor device manufacture method according to claim 5, wherein said first hard mask includes a lamination of an oxide film, a nitride film, a silicon film and a nitride film and said second hard mask is said first hard mask whose silicon film is thermally oxidized at side walls.

11. The semiconductor device manufacture method according to claim 5, wherein said first hard mask includes a lamination of an oxide film and a nitride film and said second hard mask includes said first hard mask and a silicon layer deposited on said first hard mask.

12. A semiconductor device manufacture method comprising the steps of:
(a) etching a semiconductor substrate having a high voltage transistor area and a low voltage transistor area to form isolation trenches by using a hard mask and a resist pattern formed by photolithography;
(b) thermally oxidizing surfaces of said isolation trenches;
(c) after said step (b), depositing a nitride film in said isolation trenches; and
(d) after said step (c), removing the nitride film in said isolation trench in said high voltage transistor area.

13. The semiconductor device manufacture method according to claim 12, wherein:
said hard mask includes a lamination of an oxide film and a nitride film; and
the method further comprises the step of:
(e1) after said step (d), side-etching the oxide film of said hard mask and thermally oxidizing the semiconductor substrate.

14. The semiconductor device manufacture method according to claim 12, wherein:
said hard mask includes a lamination of an oxide film and a nitride film; and
the method further comprises the step of:
(e2) between said steps (a) and (b), side-etching the oxide film of said hard mask.
